(19) United States
(12) Patent Application Publication
(10) Pub. No.: US 2019/0120625 A1
(43) Pub. Date: Apr. 25, 2019

(54) MEMS DEVICE

(71) Applicant: RICHTEK TECHNOLOGY CORPORATION, Zhubei City (TW)

(72) Inventors: Chiung-Cheng Lo, Miaoli (TW); Chiung-Wen Lin, Taichung (TW); Jye Ren, Taipei (TW)

(21) Appl. No.: 15/915,925

(22) Filed: Mar. 8, 2018

(30) Foreign Application Priority Data
Oct. 20, 2017 (CN) 201710984509.8

(51) Int. Cl. G01C 19/5712; B81B 3/00

(52) U.S. Cl. CPC G01C 19/5712; B81B 2201/0242; B81B 3/0059

(57) ABSTRACT

A MEMS device, includes: a substrate; at least two driving units, located on the substrate; at least two movable structures, respectively connected to the at least two driving units; and at least two internal mass structures, or at least one internal mass structure and at least two external mass structures, the internal mass structure being connected between the two movable structures, wherein the external mass structures are connected to and located outside the two movable structures. In response to a movement of the MEMS device, the internal mass structure rotates, and the external mass structures move in opposite directions. There is no flexible element directly connecting the mass structures, so as to reduce a coupling effect between the mass structures.

### CROSS REFERENCE

The present invention claims priority to CN 201710984509.8, filed on Oct. 20, 2017.

### BACKGROUND OF THE INVENTION

### Field of Invention

The present invention relates to a MEMS device, and especially to a MEMS device including an internal mass structure driven to rotate by movements of two movable structures in the MEMS device.

### Description of Related Art

One common type of MEMS device is gyroscope, which includes amass structure driven to vibrate by a driving unit, for sensing an angular velocity of a rotation. One prior art MEMS device includes multiple driving units which provide vibrations in different directions for sensing components of the angular velocity in various directions. Another prior art MEMS device includes relatively fewer driving units which drive multiple mass structures to vibrate for sensing the components of the angular velocity in various directions. The drawback of the former prior art MEMS device is that the structure is necessarily large, and the drawback of the latter prior art MEMS device is that a linkage between the mass structures (or a flexible element between the mass structures) is necessary for transmitting the vibration between adjacent mass structures; although the number of the driving units is reduced, the coupling effect between the mass structures may cause poor stability of the obtained sense signal.

FIG. 1 shows a conventional MEMS device 10 according to U.S. Patent No. 2014/0373628, wherein the conventional MEMS device 10 includes movable structures 23 and internal mass structures 24. The movable structures 23 are configured to drive the internal mass structures 24 for sensing a movement. There are plural linkages connected between the internal mass structures 24, for providing different combinations of movements according to different movement requirements. However, the connection between the internal mass structures 24, although provide different movement combinations, also brings a coupling effect between the internal mass structures 24, such that the movement of one internal mass structure may be coupled to affect the movement of another internal mass structure, which reduces the accuracy of the obtained sense signal. For example, when the internal mass structures 24 perform an rotation movement, it may interfere with the sensing of a translational movement, causing an error.

Besides U.S. Patent No. 2014/0373628, other prior art references such as U.S. Pat. Nos. 8,459,110, 8,833,162, 9,170,107, 2015/0211853, U.S. Pat. Nos. 9,400,180, and 9,278,845, have a similar problem of interference between the movements in different directions.

### SUMMARY OF THE INVENTION

In one perspective, the present invention provides a MEMS device, which comprises: a substrate; at least two driving units, located on the substrate; two movable structures, respectively connected to the at least two driving units; and at least two internal mass structures, connected between the two movable structures, or each internal mass structure connected between a corresponding one of the movable structures and an anchor, wherein the anchor is connected to the substrate; wherein, the at least two driving units drive the two movable structures to move in opposite directions in a first dimension, whereby the at least two internal mass structures are driven to rotate thereby; and wherein at least one of the movable structures is interposed between the at least two internal mass structures in a connection loop, and/or the at least two internal mass structures are connected to the substrate through an anchor between the at least two internal mass structures, whereby a coupling effect between the at least two internal mass structures is less than a condition that the at least two internal mass structures are connected to each other through a linkage or a flexible element.

In one embodiment, there is no flexible element directly connecting any two of the internal mass structures.

In one embodiment, the MEMS device further comprises at least one out-of-plane sensing unit, wherein the out-of-plane sensing unit includes a top electrode and a bottom electrode, respectively located on one of the internal mass structures and a position on the substrate in correspondence to the one internal mass structure, for sensing a Coriolis rotation of at least one of the internal mass structures.

In one embodiment, there are at least two out-of-plane sensing units provided in correspondence to anyone of the internal mass structures, to form a differential sensing structure.

In one embodiment, the two internal mass structures are connected to the movable structures through corresponding driving connection members, wherein when the directions of the axes of the driving connection members are in the first dimension, the axes of the two driving connection members driving the same internal mass structure 24 are separated by an offset distance, and when the directions of the axes of the driving connection members driving the same internal mass structure are not in the first dimension, the axes of the two driving connection members are collinear.

In one embodiment, each of the at least two internal mass structures is connected between one of the movable structures and the anchor, and connected to the corresponding movable structure through a corresponding driving connection member, and connected to a corresponding anchor through a corresponding fixing connection member, wherein when a direction of an axis of the driving connection member and a direction of an axis of the fixing connection member which are connected to the same internal mass structure are in the first dimension, the axis of the driving connection member and the axis of the fixing connection member are separated by an offset distance; and when a direction of an axis of the driving connection member and a direction of an axis of the fixing connection member which are connected to the same internal mass structure are not in the first dimension, the axis of the driving connection member and the axis of the fixing connection member are collinear.

In one embodiment, the movable structures are connected to each other through two elastic connection bodies.

In one embodiment, each of the elastic connection bodies includes a connecting point, wherein the two elastic connection bodies are connected to each other through the anchor, a compressional spring, or a combination of the anchor and the compressional spring, which are connected between the two connecting points of the two elastic connection bodies.

In one embodiment, each of the elastic connection bodies includes a connecting point, and the two connecting points are connected to each other through a compressional spring, or a combination of the anchor and the compressional spring, for connecting the two elastic connection bodies, wherein when the two movable structures move in opposite directions in the first dimension, the two connecting points move in opposite directions in a second dimension which is perpendicular to the first dimension.

In one embodiment, at least one of the connecting points is connected to at least one of the internal mass structures, wherein when the two movable structures move oppositely in the first dimension, the at least one connecting point drives the at least one internal mass structures to rotate.

In one embodiment, when the MEMS device rotates with an angular velocity, the at least two internal mass structures correspondingly generate at least two Coriolis rotations for sensing the angular velocity, wherein rotation axes of the at least two Coriolis rotations are not parallel to each other.

In one perspective, the present invention provides a MEMS device, comprising: a substrate; at least two driving units, located on the substrate; two movable structures, respectively connected to the at least two driving units; and at least one internal mass structure and at least two external mass structures, the at least one internal mass being structure connected between the two movable structures, the at least two external mass structures being respectively connected to outsides of the two movable structures; wherein the at least two driving units drive the two movable structures to move in opposite directions in a first dimension, whereby the at least one internal mass structure is driven to rotate, and the at least two external mass structures are driven to perform external translational movements in opposite directions.

In one embodiment, the external translational movements of the at least two external mass structures are substantially perpendicular to the first dimension. In one embodiment, the MEMS device further comprises at least one internal translational mass structure. The internal translational mass structure performs a translational movement in a direction substantially perpendicular to the first dimension.

In one embodiment, the at least one internal mass structure is connected to at least one of the movable structures through at least one driving connection member, and none of the driving connection member is directly connected to the at least two external mass structures.

In one embodiment, the substrate includes at least one anchor, and the internal mass structure further includes a fixing connection member located on an opposite side of the driving connection member, wherein this opposite side of the internal mass structure is connected to the anchor through the fixing connection member.

In one embodiment, the MEMS device comprises at least two internal mass structures. The at least two internal mass structures are separated by the at least one movable structure in a connection loop from one of the at least two internal mass structures to another of the at least two internal mass structures, and/or the at least two internal mass structures are connected to the substrate through an anchor between the at least two internal mass structures, whereby a coupling effect between the at least two internal mass structures is less than a condition that the at least two internal mass structures are connected to each other through a linkage.

In one embodiment, when the MEMS device rotates with an angular velocity, the at least two internal mass structures correspondingly generate at least two Coriolis rotations for sensing the angular velocity, wherein rotation axes of the at least two Coriolis rotations are not parallel to each other.

In one embodiment, the MEMS device further comprises at least one out-of-plane sensing unit and at least two translation sensing units, wherein the out-of-plane sensing unit includes a top electrode and a bottom electrode, respectively located on one of the internal mass structures and a position on the substrate in correspondence to the one internal mass structure, for sensing a Coriolis rotation of the internal mass structure, and wherein each of the translation sensing units includes a movable electrode and a fixed electrode, respectively located on one of the external mass structures and a position on the substrate in correspondence to the one external mass structure, for sensing an external translational movement of the external mass structures in correspondence to a Coriolis effect.

### BRIEF DESCRIPTION OF THE DRAWINGS

FIG. 1 shows a prior art MEMS device.

FIGS. 2, 3, 4, 5, 6A, 6B, and 7 show MEMS devices according to several embodiments of the present invention.

FIGS. 8 and 9 respectively show a static status and a moving status of the MEMS device according to one embodiment of the present invention.

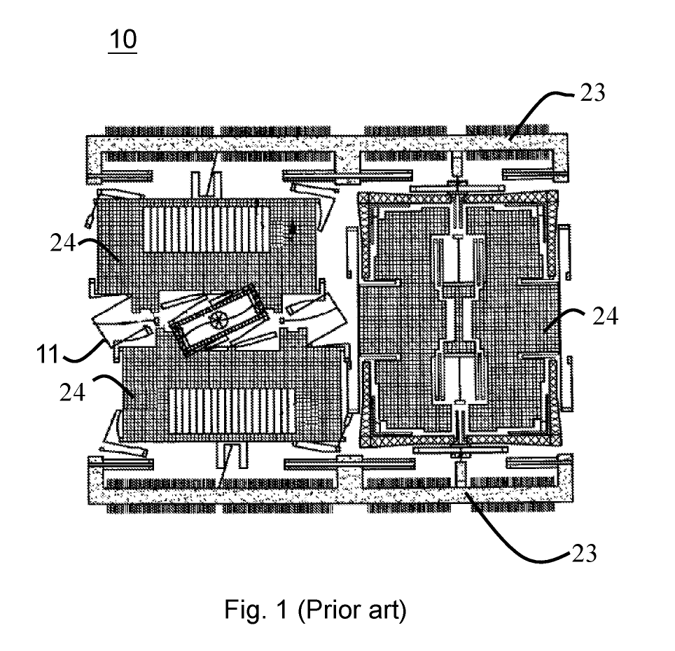

### DESCRIPTION OF THE PREFERRED EMBODIMENTS

The drawings as referred to throughout the description of the present invention are for illustrative purpose only, to show the interrelations between the components, but not drawn according to actual scale.

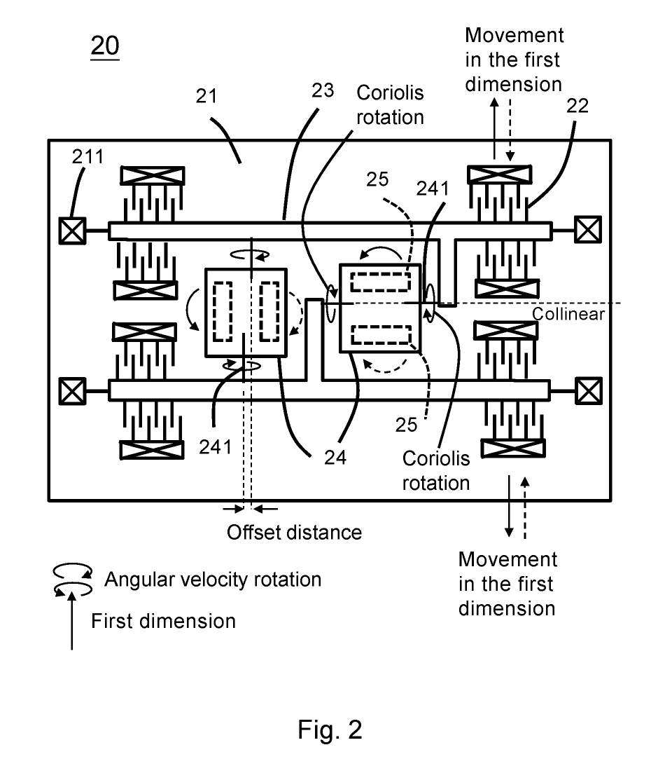

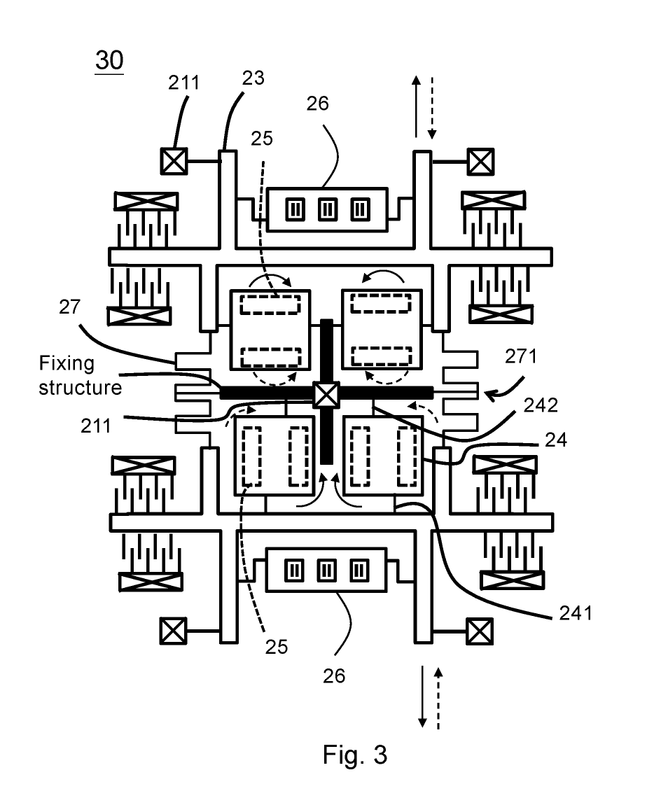

FIG. 2 shows a MEMS device 20 according to one embodiment of the present invention. The MEMS device 20 comprises: a substrate 21; at least two driving units 22, located on the substrate 21; two movable structures 23, respectively connected to the at least two driving units 22; and at least two internal mass structures 24, connected between the two movable structures 23 (only two internal mass structures 24 are shown in FIG. 2, but the number of the internal mass structures is for example and is not limited to two. For example, there are four internal mass structures 24 shown in FIG. 3). Each of the internal mass structures 24 is connected to other parts of the MEMS device through at least one driving connection member 241 (each of the internal mass structures 24 in FIG. 2 is connected to two driving connection members 241, and each internal mass structure 24 in FIG. 3 is connected to one driving connection member 241 and one fixing connection member 242). In FIG. 2, each of the internal mass structures 24 is connected to two movable structures 23 through two driving connection members 241 respectively. In one embodiment, the driving connection member 241 and/or the fixing connection member 242 is integrated with the internal mass structure 24 in one piece (i.e. the driving connection member 241 and/or the fixing connection member 242 is a portion of the internal mass structure 24). Or in another embodiment, the driving connection member 241 and/or the fixing connection member 242 is a separated different structure from the internal mass structure 24. The at least two driving units 23 are configured to drive the two movable structures 23 to move in opposite directions in a first dimension (straight solid arrows and straight dashed arrows in FIG. 2), and the movements of the two movable structures 23 drive the at least two internal mass structures 24 to rotate (curved solid arrows and curved dashed arrows in FIG. 2).

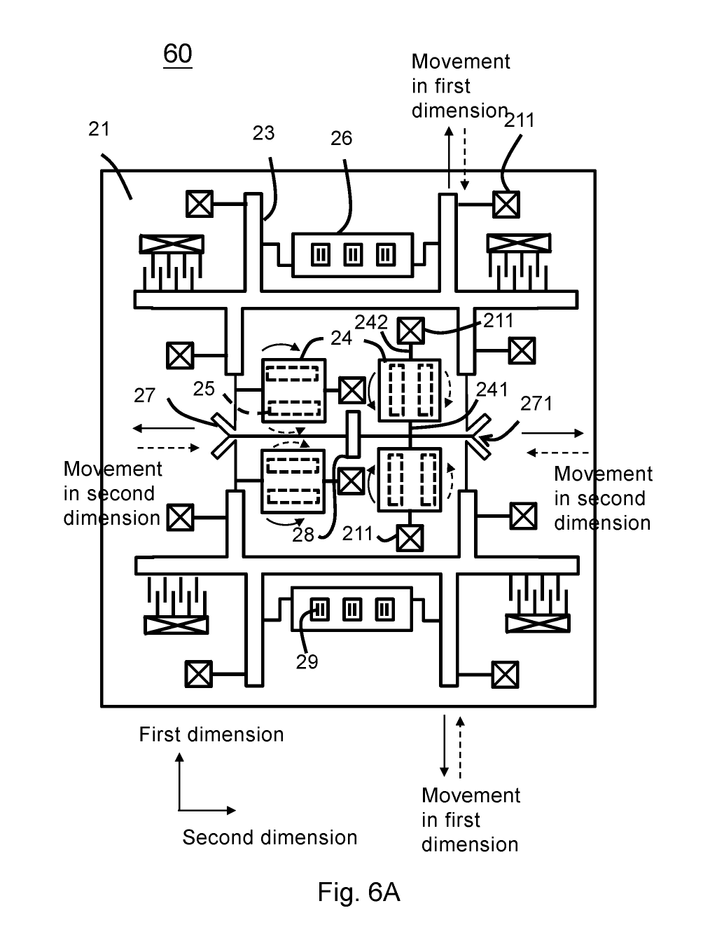

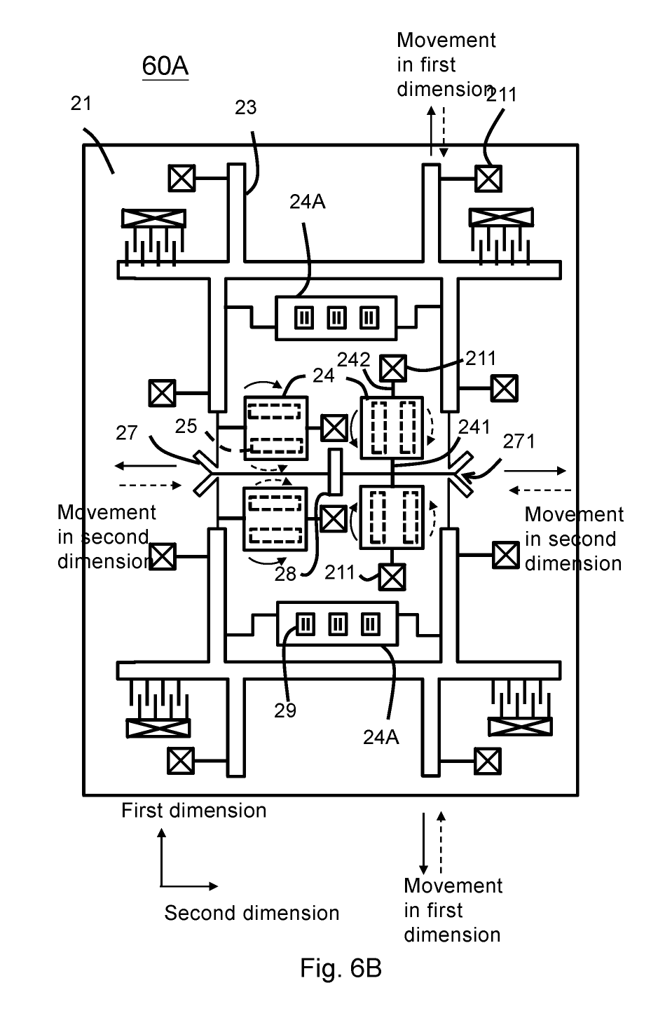

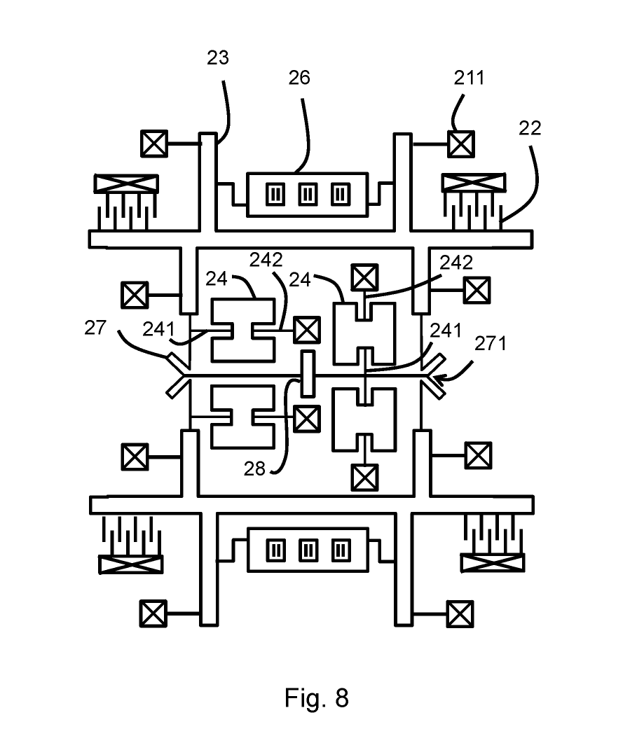

In one embodiment, the driving connection member 241 and the fixing connection member 242 are flexible components, for providing an elastic connection between the movable structure 23 and the anchor 211 (FIGS. 3, 5, 6A, and 8), or between the movable structure 23 and an elastic connection body 27 (FIGS. 6A and 8). However, note that in the present invention, the fixing connection member 242 is an optional component. For example, in the embodiments of FIGS. 2, 4, and 7, there is no fixing connection member 242 included in the MEMS devices 20, 40, and 70. According to the present invention, the connection by the driving connection member 241 or the fixing connection member 242 can be arranged according to different designs.

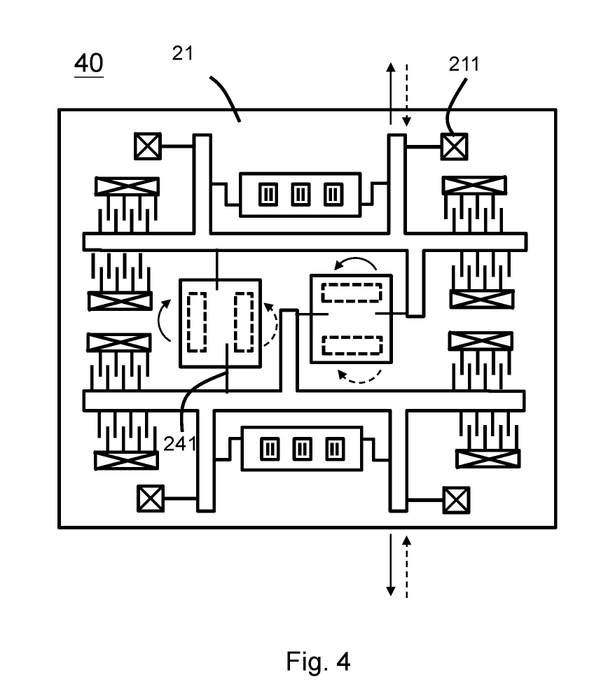

In the aforementioned embodiment, the opposite movements of the two movable structures 23 in the first dimension are two outward movements in the first dimension (straight solid arrows), or two inward movements in the first dimension (straight dashed arrows). Correspondingly, the two internal mass structures 24 are driven to rotate in different directions (curved solid arrows and curved dashed arrows). Note that, although the two internal mass structures 24 rotate by the same direction, the rotations are independent from each other. In another embodiment, the rotations of the internal mass structures 24 maybe in opposite directions. For example, in the MEMS device 40 in FIG. 4, the rotations of the two internal mass structures 24 are in opposite directions.

In the embodiment of FIG. 3, the substrate 21 includes at least one anchor 211, and the internal mass structure 24 further includes a fixing connection member 242 located at an opposite side of the driving connection member 241, wherein this opposite side of the internal mass structure 24 is connected to the anchor 211 through the fixing connection member 242. The fixing connection member 242 connected to the anchor 211 (and through the anchor 211 to the substrate 21) can provide a rotation pivot or a swing pivot of the internal mass structure 24. In the embodiment of FIG. 3, the opposite movements (straight solid arrows and straight dashed arrows) of the two movable structures 23 drive the internal mass structures 24 to rotate (curved solid arrows and curved dashed arrows, correspondingly).

In the MEMS devices 20 and 30 of FIGS. 2 and 3, there is neither linkage nor flexible element directly connecting any two of the internal mass structures 24; the internal mass structures 24 are individually driven by the movable structure 23. From another perspective, in the embodiment of FIG. 2, it can be regarded as that each one of the movable structures 23 is interposed between two internal mass structures 24 and separate the two internal mass structures 24 in a connection loop from one internal mass structure 24, through one driving connection member 241, the movable structure 23, another driving connection member 241, to the other internal mass structure 24. In the embodiment of FIG. 3, it can be regarded as that the internal mass structures 24 are separated by the movable structure 23, and/or separated by the anchor 211 (or an extension part of the anchor 211; in one embodiment, the extension part maybe regarded as a portion of the anchor 211). In comparison with the prior art which uses linkages between the internal mass structures, in the present invention, each of the internal mass structures 24 rotates individually, and the rotation of one internal mass structure 24 will not be coupled to another internal mass structure 24. Therefore, the present invention can provide more accurate sense signals than the prior art.

In FIGS. 2 and 3, the MEMS devices 20 and 30, both further comprise plural out-of-plane sensing units 25. Each of the out-of-plane sensing units 25 includes a top electrode and a bottom electrode, respectively located on one of the internal mass structures 24 and a corresponding position above or below the internal mass structure 24; the corresponding position for example can be a position on the substrate 21, below the internal mass structure 24. By out-of-plane movements of the out-of-plane sensing units 25, Coriolis rotations of the internal mass structures 24 can be sensed. Each of the internal mass structures 24 includes a body portion between the driving connection members 241 or between the driving connection member 241 and the fixing connection member 242, which is a one-piece integral structure. The “one-piece integral structure”, from one perspective, can be understood as: when the internal mass structure 24 moves, every portion of the internal mass structure 24 has the same movement direction; or, a sensing error due to mismatch between different portions of the internal mass structure 24 is trivial and negligible.

One example of the aforementioned Coriolis rotation is shown in the right internal mass structure 24 in FIG. 2, wherein when the two movable structures 23 move in opposite directions in the first dimension, the right internal mass structure 24 rotates correspondingly as shown in FIG. 2. More specifically, for example, when the MEMS device 20 rotates in accordance with a rotation axis extending in the first dimension, the right internal mass structure 24 is driven to have a corresponding Coriolis rotation as shown in FIG. 2. As such, the rotation and the angular velocity of the MEMS device 20 can be determined by the Coriolis rotation which is sensed by the out-of-plane sensing unit or units 25.

According to the present invention, the out-of-plane sensing unit or units 25 corresponding to each of the internal mass structures 24 only senses the rotation in one corresponding rotation axis. Thus, the sensing results of the Coriolis rotations of the internal mass structures 24 do not interfere with each other; that is, the present invention produces no coupling effect between the sensing results of the Coriolis rotations of the internal mass structures 24, so the sensing accuracy is better than the prior art. In the embodiment of FIG. 2, at least two Coriolis rotations are generated by the internal mass structures 24, and the rotation axes of the generated Coriolis rotations are not parallel to each other. That is, if there are two or more internal mass structures, the rotation axes of different internal mass structures may be not parallel to each other, for sensing the rotation and the angular velocity.

Still referring to FIGS. 2 and 3, in one embodiment, two out-of-plane sensing units 25 are provided in correspondence with each of the internal mass structures 24, which are located symmetrically with respect to a rotation axis of the out-of-plane rotation, to form a differential sensing structure, for increasing the sensing accuracy.

In one embodiment, each of the movable structures 23, is substantially a one-piece integral structure. The “one-piece integral structure”, from one perspective, can be understood as: when the movable structure 23 moves, every portion of the movable structure 23 has the same movement direction. By the one-piece integral structure of each of the movable structure 23, when the movable structures 23 move oppositely in the first dimension, every portion of each of the movable structures 23 has the same movement direction, and because the internal mass structures 24 are connected between the movable structures 23, the internal mass structures 24 rotate simultaneously and synchronously. As such, the one-piece integral structure can provide more precise control of the rotations of the internal mass structures 24.

In the embodiment of FIG. 2, each of the internal mass structures 24 is driven to rotate by two driving connection member 241 respectively connecting the opposite sides of the internal mass structures 24 to the two movable structures 23.

As shown in FIG. 2, the two driving connection members 241 of the right internal mass structure 24 are collinear, while the axes of the two driving connection members 241 of the left internal mass structure 24 are not collinear and separated by an offset distance. In one embodiment, in order to drive the internal mass structures 24 to rotate, when the directions of the axes of the driving connection members 241 are in the first dimension (i.e., parallel to the opposite movements of the movable structures 23), the axes of the two driving connection members 241 driving the same internal mass structure 24 are preferably separated by an offset distance; while, when the directions of the axes of the driving connection members 241 are not in the first dimension, the axes of the two driving connection members 241 driving the same internal mass structure 24 may be collinear. Please refer to FIG. 3, wherein the collinear or offset arrangement between the driving connection member 241 and the fixing connection member 242 are similar to the driving connection members 241 in the embodiment of FIG. 2.

In the embodiment of FIG. 2, the MEMS device 20 can perform Coriolis rotations of two different directions, for sensing a two-dimensional angular velocity; with the two-dimensional sensing capability, the MEMS device 20 for example can be a gyroscopic device. However, the MEMS device is not limited to a gyroscopic device with a two-dimensional sensing capability; according to the present invention, the MEMS device can be a gyroscopic device with a three-dimensional sensing capability. For example, the MEMS device 20 of FIG. 3 includes the internal mass structures 24 for the two-dimensional sensing purpose, and further includes two external mass structures 26 for sensing a Coriolis rotation in a further other rotation direction; the related details will be explained later.

Please refer to FIG. 3, wherein the two movable structures 23 are preferably connected to each other through two elastic connection bodies 27, for controlling the two movable structures 23 to move oppositely in the first dimension.

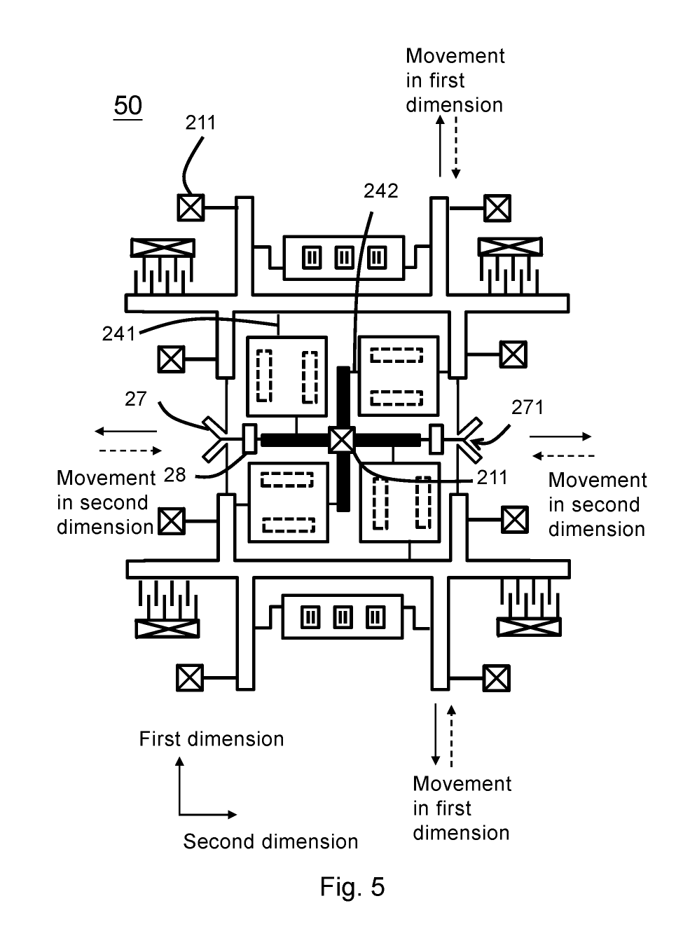

More specifically, referring to FIG. 3, each of the elastic connection bodies 27 includes a connecting point, and the two connecting points 271 of the two elastic connection bodies 27 are connected to each other through one or more anchors 211 in between. In another embodiment, the two connecting points 271 of the two elastic connection bodies 27 are connected to each other through a compressional spring 28 (in the MEMS device 60 of FIG. 6A), or, in another embodiment, through a combination of one or more anchors 211 and one or more compressional springs 28 (in the MEMS device 50 of FIG. 5). In brief, the connection between the connecting points 271 can be arranged in many ways. The two movable structures are connected to each other through the two elastic connection bodies 27. Regardless whether the connecting points 271 are connected to each other through one or more anchors 211, through one or more compressional springs 28, or through a combination of one or more anchors 211 and one or more compressional springs 28, anyone of the above layouts can restrict the movements of the connecting points 271 in the first dimension. That is, in a different perspective, the connection between the connecting points 271 helps to maintain the middle point between the two movable structures 23 in a steady position without undesired movement in the first dimension, so that the elastic connection bodies 27 can assist the opposite movements of the two movable structures 23.

Although the connecting points 271 of the elastic connection bodies 27 can maintain the middle point between the two movable structures 23 in a steady position without undesired movement in the first dimension, the connecting points 271 are movable in other directions if required. In FIGS. 6A and 5, the two connecting points 271 are connected to each other through one or more compressional springs 28, or a combination of one or more compressional springs 28 and one or more anchors 211. In these embodiments, when the two movable structures 23 move oppositely in the first dimension, the two connecting points 271 move oppositely in the second dimension, wherein the second dimension is substantially perpendicular to the first dimension. The wording “substantially perpendicular” means that a certain error is tolerable.

In the embodiment of FIG. 6A, at least one of the connecting points 271 (the connecting point 271 of the right elastic connection body 27) is connected to at least two internal mass structures 24 (that is, in the connection loop, the connecting point 271 is closer to the two internal mass structures 24 than any other portion of the right elastic connection body 27). When the two movable structures 23 move oppositely in the first dimension, the at least one connecting point 271 drives the at least two internal mass structures 24 to rotate (curved solid arrows and curved dashed arrows in FIG. 6A). In the left side of FIG. 6A, the internal mass structures 24 are not connect to the connecting point 271 of the left elastic connection body 27 (that is, in the connection loop, the connecting point 271 is not the closest point to the two internal mass structures 24 than any other portion of the left elastic connection body 27). Each of the left internal mass structures 24 is connected to a point between the movable structure 23 and the connecting point 271, and is driven to rotate (curved solid arrows and curved dashed arrows in FIG. 6A).

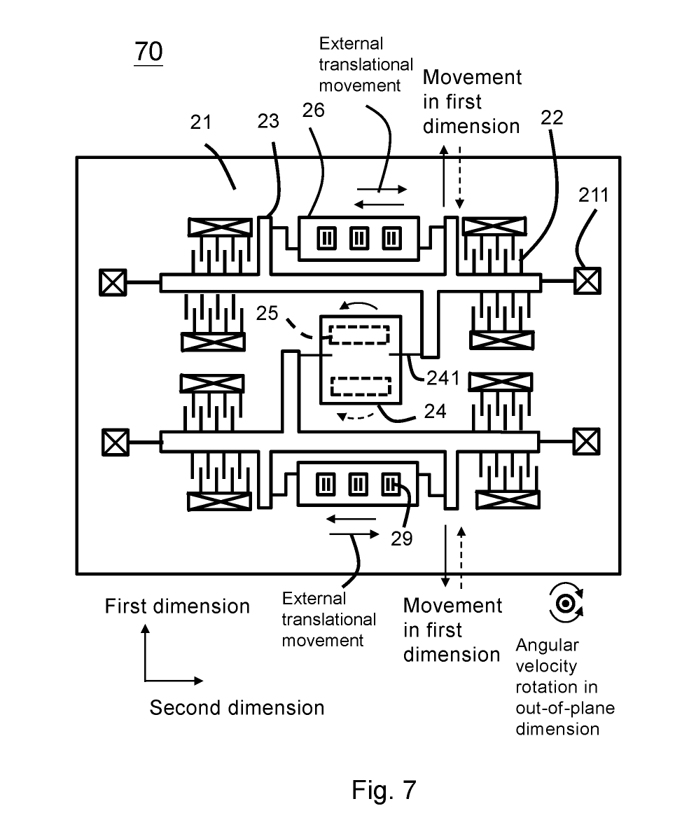

Referring to FIG. 7, in another embodiment, the present invention provides a MEMS device 70, which comprises: a substrate 21; at least two driving units 22, located on the substrate 21; two movable structures 23, respectively connected to the at least two driving units 22; and at least one internal mass structure 24 and at least two external mass structures 26, the at least one internal mass structure 24 being connected between the two movable structures 23, the at least two external mass structures 26 being respectively located outside the two movable structures 23 and connected to the two movable structures 23; wherein each of the internal mass structures 24 is connected to one of the movable structure 23 through a driving connection member 241; and wherein the at least two driving units 24 drive the two movable structures 23 to move (straight solid arrows and straight dashed arrows) in opposite directions in a first dimension, whereby the at least one internal mass structure 24 connected between the movable structures 23 is driven to rotate (curved solid line and curved dashed line), and the at least two external mass structures 26 are driven to perform translational movements in opposite directions (“external translational movements” hereinafter because these movements are outside the two movable structures 23). When the MEMS device 70 rotates out-of-plane with an angular velocity, by the Coriolis effect, the two external mass structures 26 are driven to perform external translational movements (solid arrows) in a second dimension. The second dimension is substantially perpendicular to the first dimension. When the two movable structures 23 moves oppositely in the first dimension, the two external mass structures 26 move oppositely in the second dimension. For example, when the top external mass structure 26 moves leftward, the bottom external mass structure 26 moves rightward. Or, when the top external mass structure 26 moves rightward, the bottom external mass structure 26 moves leftward.

FIG. 6B shows a MEMS device 60A according to one embodiment of the invention, wherein the MEMS device 60A includes at least one internal translational mass structure 24A (for example, two internal translational mass structures 24A shown in FIG. 6B). These internal translational mass structures 24A can perform translational movements whose directions are substantially perpendicular to the first dimension. The translational movements of the internal translational mass structures 24A are similar to the movements of the external mass structures 26.

Referring to FIG. 6A, the MEMS device 60 may have plural internal mass structures 24 and plural external mass structures 26. The internal mass structure 24 provides a gyroscopic function to sense an in-plane rotation (i.e., the axis of the rotation is along an in-plane direction), while the external mass structures 26 provides a sensing function in a third dimension. Thus, the MEMS device 60 is a gyroscope having a three-dimensional sensing capability.

In FIG. 7, the driving connection member 241 connected to the internal mass structure 24 is not directly connected to the external mass structures 26. Thus, the rotation of each of the internal mass structures 24 does not directly affect the external translational movement of the external mass structures 26, so that a coupling effect between the internal mass structures 24 and the external mass structures 26 can be avoided, whereby the sensing accuracy is improved.

Referring to the embodiments of FIGS. 5 and 6A, the substrate 21 includes at least one anchor 211. The internal mass structure 24 further includes a fixing connection member 242 located on the opposite side of the driving connection member 241, wherein this opposite side of the internal mass structure 24 is connected to the anchor 211 through the fixing connection member 242.

In the embodiments of FIGS. 6A and 7, the MEMS devices 60 and 70 further include plural out-of-plane sensing units 25 and plural translation sensing units 29. Each of the out-of-plane sensing units 25 includes two electrodes, respectively located on one of the internal mass structures 24 and a position on the substrate 21 in correspondence to the one internal mass structure 24. Each of the translation sensing units 29 includes two electrodes, respectively located on one of the external mass structures 26 and a position on the substrate 21 in correspondence to the one external mass structure 26 on the substrate 21, wherein the two electrodes for example includes a movable electrode located on the external mass structures 26, and a fixed electrode located on the position on the substrate 21 in correspondence to the one external mass structure 26. In one embodiment, there are plural out-of-plane sensing units 25 and/or plural translation sensing units 29 corresponding to each internal mass structure 24 and each external mass structure 26 respectively, for increasing sensing accuracy.

In the embodiment of FIG. 7, the two movable structures 23 are respectively connected to two opposite sides of the internal mass structure 24 through two driving connection members 241, to drive the internal mass structures 24 to rotate.

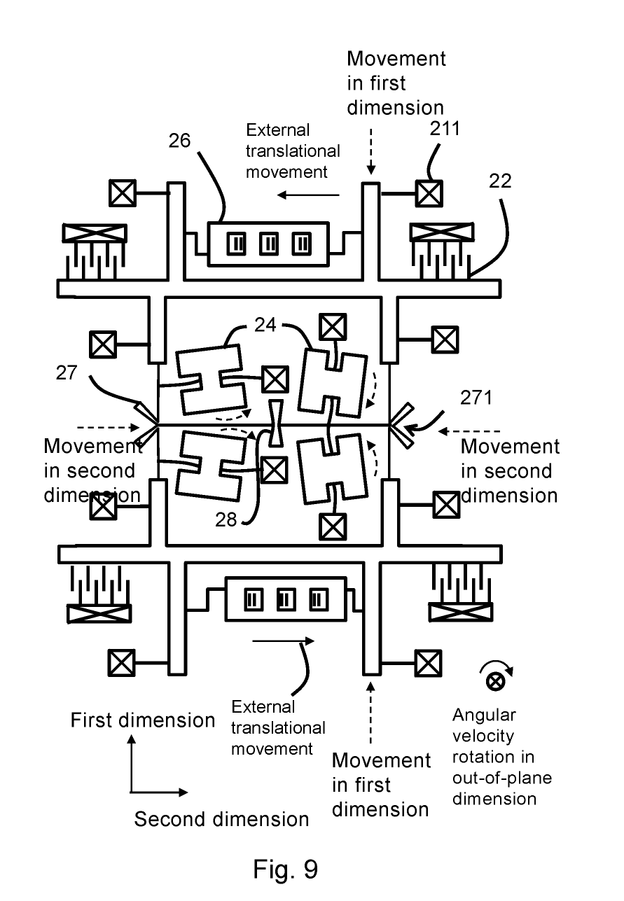

FIGS. 8 and 9 show one embodiment of the MEMS device, for illustrating the rotations of the internal mass structures 24 and the external translational movements of the external mass structures 26, wherein the MEMS device is similar to the MEMS device 60 of FIG. 6A. FIG. 8 shows a stationary state wherein the movable structures 23 do not move, and hence neither the internal mass structures 24 rotate, nor the external mass structures 26 move. FIG. 9 shows that when the movable structures 23 move in the first dimension (dashed line), the internal mass structures 24 rotates (dashed line). Further, when MEMS device rotates (for example, an out-of-plane rotation) and the movable structures 23 move in the first dimension, the external mass structures 26 correspondingly perform translational movements as shown in FIG. 9. The angular velocity of the out-of-plane rotation can be determined according to the translational movements of the external mass structures 26.

In the aforementioned embodiments, the number of the internal mass structures 24 or the external mass structures 26 can be modified according to different requirements in different applications, not limited to the number of mass structures shown in figures. In FIGS. 3, 5, 8, and 9, the substrate is not shown for clarity of the drawing; however, although not shown, the anchors in these embodiments are located on and connected to the substrates.

The present invention has been described in considerable detail with reference to certain preferred embodiments thereof. It should be understood that the description is for illustrative purpose, not for limiting the scope of the present invention. Those skilled in this art can readily conceive variations and modifications within the spirit of the present invention. Besides, an embodiment or a claim of the present invention does not need to attain or include all the objectives, advantages or features described in the above. The abstract and the title are provided for assisting searches and not to be read as limitations to the scope of the present invention. It is not limited for each of the embodiments described hereinbefore to be used alone; under the spirit of the present invention, two or more of the embodiments described hereinbefore can be used in combination. All such modifications and variations should fall in the scope of the present invention.

What is claimed is:

1. A MEMS device, comprising:
a substrate;
at least two driving units, located on the substrate;
two movable structures, respectively connected to the at least two driving units; and
at least two internal mass structures, connected between the two movable structures, or each internal mass structure connected between a corresponding one of the movable structures and an anchor, wherein the anchor is connected to the substrate;
wherein, the at least two driving units drive the two movable structures to move in opposite directions in a first dimension, whereby the at least two internal mass structures are driven to rotate thereby; and
wherein at least one of the movable structures is interposed between the at least two internal mass structures in a connection loop from one of the at least two internal mass structures to another of the at least two internal mass structures, and/or the at least two internal mass structures are connected to the substrate through an anchor between the at least two internal mass structures, whereby a coupling effect between the at least two internal mass structures is less than a condition that the at least two internal mass structures are connected to each other through a linkage.

2. The MEMS device of claim 1, wherein there is no flexible element directly connecting any two of the internal mass structures.

3. The MEMS device of claim 1, further comprising at least one out-of-plane sensing unit, wherein the out-of-plane sensing unit includes a top electrode and a bottom electrode, respectively located on one of the internal mass structures and a position on the substrate in correspondence to the one internal mass structure, for sensing a Coriolis rotation of at least one of the internal mass structures.

4. The MEMS device of claim 3, wherein there are at least two out-of-plane sensing units provided in correspondence to anyone of the internal mass structures, to form a differential sensing structure.

5. The MEMS device of claim 1, wherein the two internal mass structures are connected to the movable structures through corresponding driving connection members; wherein when directions of the axes of the driving connection members are in the first dimension, the axes of the two driving connection members driving the same internal mass structure are separated by an offset distance, and when directions of the axes of the driving connection members driving the same internal mass structure are not in the first dimension, the axes of the two driving connection members are collinear.

6. The MEMS device of claim 1, wherein each of the at least two internal mass structures is connected between one of the movable structures and the anchor, and connected to the corresponding movable structure through a corresponding driving connection member, and connected to a corresponding anchor through a corresponding fixing connection member; wherein when a direction of an axis of the driving connection member and a direction of an axis of the fixing connection member which are connected to the same internal mass structure are in the first dimension, the axis of the driving connection member and the axis of the fixing connection member are separated by an offset distance; and when a direction of an axis of the driving connection member and a direction of an axis of the fixing connection member which are connected to the same internal mass structure are not in the first dimension, the axis of the driving connection member and the axis of the fixing connection member are collinear.

7. The MEMS device of claim 1, wherein the movable structures are connected to each other through two elastic connection bodies.

8. The MEMS device of claim 7, wherein each of the elastic connection bodies includes a connecting point, wherein the two elastic connection bodies are connected to each other through the anchor, a compressional spring, or a combination of the anchor and the compressional spring, which are connected between the two connecting points of the two elastic connection bodies.

9. The MEMS device of claim 7, wherein each of the elastic connection bodies includes a connecting point, and the two connecting points are connected to each other through a compressional spring, or a combination of the anchor and the compressional spring, for connecting the two elastic connection bodies, wherein when the two movable structures move in opposite directions in the first dimension, the two connecting points move in opposite directions in a second dimension which is perpendicular to the first dimension.

10. The MEMS device of claim 8, wherein at least one of the connecting points is connected to at least one of the connecting points is connected to at least one of the internal mass structures, wherein when the two movable structures move oppositely in the first dimension, the at least one connecting point drives the at least one internal mass structures to rotate.

11. The MEMS device of claim 1, wherein when the MEMS device rotates with an angular velocity, the at least two internal mass structures correspondingly generate at least two Coriolis rotations for sensing the angular velocity, wherein rotation axes of the at least two Coriolis rotations are not parallel to each other.

12. A MEMS device, comprising:
a substrate;
at least two driving units, located on the substrate;
two movable structures, respectively connected to the at least two driving units; and
at least one internal mass structure and at least two external mass structures, the at least one internal mass being structure connected between the two movable structures, the at least two external mass structures being respectively connected to outsides of the two movable structures;
wherein the at least two driving units drive the two movable structures to move in opposite directions in a first dimension, whereby the at least one internal mass structure is driven to rotate, and the at least two external mass structures are driven to perform external translational movements in opposite directions.

13. The MEMS device of claim 12, wherein directions of the external translational movements of the at least two external mass structures are perpendicular to the first dimension.

14. The MEMS device of claim 12, wherein the at least one internal mass structure is connected to at least one of the movable structures through at least one driving connection member, and none of the driving connection member is directly connected to the at least two external mass structures.

15. The MEMS device of claim 14, wherein the substrate includes at least one anchor, and the internal mass structure further includes a fixing connection member located on an opposite side of the driving connection member, wherein this opposite side of the internal mass structure is connected to the anchor through the fixing connection member.

16. The MEMS device of claim 12, comprising at least two internal mass structures, wherein the at least two internal mass structures are separated by the at least one movable structure in a connection loop from one of the at least two internal mass structures to another of the at least two internal mass structures, and/or the at least two internal mass structures are connected to the substrate through an anchor between the at least two internal mass structures, whereby a coupling effect between the at least two internal mass structures is less than a condition that the at least two internal mass structures are connected to each other through a linkage.

17. The MEMS device of claim 16, wherein when the MEMS device rotates with an angular velocity, the at least two internal mass structures correspondingly generate at least two Coriolis rotations for sensing the angular velocity, wherein rotation axes of the at least two Coriolis rotations are not parallel to each other.

18. The MEMS device of claim 12, further comprising at least one out-of-plane sensing unit and at least two translation sensing units, wherein the out-of-plane sensing unit includes a top electrode and a bottom electrode, respectively located on one of the internal mass structures and a position on the substrate in correspondence to the one internal mass structure, for sensing a Coriolis rotation of the internal mass structure, and wherein each of the translation sensing units includes a movable electrode and a fixed electrode, respectively located on one of the external mass structures and a position on the substrate in correspondence to the one external mass structure, for sensing an external translational movement of the external mass structures in correspondence to a Coriolis effect.
